(19) United States
(12) Patent Application Publication
(10) Pub. No.: US 2001/0039114 A1
(43) Pub. Date: Nov. 8, 2001

(54) Method Of Forming Contact Or Wiring In Semiconductor Device

(76) Inventor: Ryoichi Nakamura, Tokyo (JP)

Correspondence Address: Sughrue Mion Zinn Macpeak & Seas, 2100 Pennsylvania Avenue NW, Washington, DC, 20037, US

(21) Appl. No.: 09/478,892

(22) Filed: Jan. 7, 2000

(30) Foreign Application Priority Data
Jan. 8, 1999 (JP) 11-003538

(51) Int. Cl. H01L 21/44; H01L 21/4763

(52) U.S. Cl. 438/638; 438/634; 438/637; 438/668; 438/672; 438/675

(57) ABSTRACT

An interlayer insulating film and a first insulating film are formed on a semiconductor substrate. A resist is applied on the first insulating film and then patterning the same so that an opening at an area to form a contact hole has a diameter greater than the width of an opening at an area to form a wiring groove or that an opening at an area to form a deep contact hole is greater in diameter than an opening at an area to form a shallow contact hole. This allows a contact hole and a wiring groove, or a deep contact hole and a shallow contact hole, to be formed by a single photolithographic process.

### BACKGROUND OF THE INVENTION

1. Field of the Invention

The present invention relates to a method for forming contacts or wiring in a semiconductor device. In particular, the present invention relates to a method for forming contact or wiring in a semiconductor device, the method being capable of simultaneously forming contact holes having different depths, or a wiring groove and a contact hole.

2. Description of the Related Art

Recently, many techniques have been developed of dual damascening in which contact holes or wiring grooves are formed in an insulating film and then a metal layer is deposited over the insulating film. Then, the metal layer is subjected to chemical mechanical polishing (hereinafter, referred to as CMP).

Moreover, there have been proposed several methods of forming both shallow contacts and deep contacts, including those disclosed in Japanese Patent Application Laid-Open Nos. Hei 10-116904, Hei 7-201992, and Hei 8-335634. In any of these conventional methods, wiring grooves and contact holes are formed by using separate photolithographic processes.

Accordingly, the aforementioned methods of forming shallow and deep contacts require a plurality of photolithographic processes, which increases the number of processes. In addition, the conventional methods have a drawback of causing alignment errors and the like due to the use of more than one photolithographic process.

Meanwhile, Japanese Patent Application Laid-Open No. Hei 8-107143 discloses a method for forming both wiring grooves and contact holes by a single photolithographic process.

FIGS. 1A and 1B are sectional views showing a conventional method for forming contact holes in the order of its processes. As shown in FIG. 1A, an interlayer insulating film 101 is initially formed on a semiconductor substrate 100. Here, a first wiring layer 102 and a second wiring layer 103 are embedded in the interlayer insulating film 101 so as to differ from each other in height within the interlayer insulating film 101. Then, on the interlayer insulating film 101 is formed a resist film 104, which is patterned by photolithography to have openings at contact hole forming positions.

Next, as shown in FIG. 1B, the interlayer insulating film 101 is subjected to anisotropic dry etching with the resist film 104 as a mask. This forms a deep contact hole 106 which reaches to the first wiring layer 102 and a shallow contact hole 105 which reaches to the second wiring layer 103. In this manner, the shallow contact hole 105 and deep contact hole 106 are formed.

When, however, the method described in Japanese Patent Application Laid-Open No. Hei 8-107143 mentioned above is adopted to form both the deep contact hole 106 and the shallow contact hole 105 by a single photolithographic process and anisotropic etching, the difference in etch depth within the interlayer insulating film 101 gives rise to a problem of technical difficulties in manufacturing.

Besides, as shown in FIGS. 1A and 1B, the method using a single photolithographic process to form both a shallow contact hole 105 and a deep contact hole 106, though being small in the number of processes and simple, results in a longer etch time to the second wiring layer 103 that is to receive the shallow contact hole 105, causing a problem of increasing damage to the second wiring layer 103. The extended etch time to the second wiring layer 103 also produces a problem in that the shallow contact hole 105 may run through the second wiring layer 103.

### SUMMARY OF THE INVENTION

An object of the present invention is to provide a method for forming contacts or wiring in a semiconductor device, the method being capable of forming a contact hole and a wiring groove, or a deep contact hole and a shallow contact hole, simultaneously by a single photolithographic process.

A method for forming contact or wiring in a semiconductor device according to a first invention of the present application comprises the steps of: forming an interlayer insulating film on a semiconductor substrate; forming a first insulating film on said interlayer insulating film; and applying a resist on said first insulating film and then patterning the same to form a first opening and a second opening at an area to form a contact hole and an area to form a wiring groove, respectively. A diameter of the first opening at the area to form the contact is greater than the width of the second opening at the area to form the wiring groove.

According the second claim of the invention, following steps are provided, after patterning the resist: forming a hole and a wiring groove at the area of the first opening and the area of second opening, respectively, in the first insulating film and the interlayer insulating film; forming a second insulating film over said hole and said wiring groove and forming a sidewall in said hole at the area to form a contact hole as well as fill said wiring groove therewith; forming a contact hole at said hole in the interlayer insulating film by etching back said interlayer insulating film with said sidewall and said second insulating film as a mask; and removing said sidewall and said second insulating film.

A method for forming contacts or wiring in a semiconductor device according to another aspect of the invention comprises the steps of: forming an interlayer insulating film on a semiconductor substrate; forming a first insulating film on said interlayer insulating film; and applying a resist on said first insulating film and then patterning the same to form a first opening and a second opening at an area to form a deep contact hole and an area to form a shallow contact hole, respectively. A diameter of the first opening at the area to form the deep contact hole is greater than a diameter of the second opening at the area to form a shallow contact hole.

After patterning the resist, the present invention may comprise the following steps: forming a hole and a shallow contact hole at the area of the first opening and the area of the second opening, respectively, in the first insulating film and the interlayer insulating film; forming a second insulating film over said hole and said shallow contact hole and forming a sidewall in said hole at the area to form a deep contact hole as well as fill said shallow contact hole therewith; forming a deep contact hole at said hole in the interlayer insulating film by etching back said interlayer insulating film with said sidewall and said second insulating film as a mask; and removing said sidewall and said second insulating film.

In this case, after forming said sidewall in said hole and said second insulating film in said shallow contact hole, a deep contact hole may be formed and said second film in said shallow contact hole may be removed simultaneously by etching back said interlayer insulating film with said sidewall and said second insulating film as a mask and then etching back said sidewall and said second insulating film.

Said interlayer insulating film may be made of one material selected from the group consisting of SiO₂, BPSG, and PSG, or any laminate structure of the same.

According to the present invention, the resist is patterned so that a first opening at the area to form a contact hole has a diameter greater than the width of a second opening at the area to form a wiring groove. This allows the second insulating film, when formed thereover, to fill the wiring groove, while not filling the contact hole. This provides separate controls as to the depths of the wiring groove and the contact hole. Therefore, both the wiring groove and the contact hole can be formed by a single photolithographic process rather than by a plurality of photolithographic processes.

Moreover, according to the present invention, the resist is patterned so that a first opening at the area to form a deep contact hole is greater in diameter than a second opening at the area to form a shallow contact hole. This allows the second insulating film, when formed thereover, to fill the shallow contact hole, while not filling the deep contact hole. This provides separate controls as to the depths of the shallow contact hole and the deep contact hole. Therefore, both the shallow and deep contact holes can be formed by a single photolithographic process rather than by a plurality of photolithographic processes.

The nature, principle and utility of the invention will become more apparent from the following detailed description when read in conjunction with the accompanying drawings.

### BRIEF DESCRIPTION OF THE DRAWINGS

FIGS. 1A and 1B are sectional views showing a conventional method for forming contact holes in the order of its processes;

FIGS. 2 through 10 are sectional views showing the method for forming contacts or wiring in a semiconductor device according to a first embodiment of the present invention, in the order of its steps;

FIG. 11 is a top view of FIG. 10;

FIG. 12 is a sectional view taken along the line A-A in FIG. 11;

FIGS. 13 through 19 are sectional views showing the method for forming contacts or wiring in a semiconductor device according to a second embodiment of the present invention, in the order of its steps;

FIG. 20 is a top view of FIG. 19;

FIG. 21 is a sectional view showing the process which follows that of FIG. 19;

FIG. 22 is a top view of FIG. 21; and

FIGS. 23 through 28 are sectional views showing the method for forming contacts or wiring in a semiconductor device according to a third embodiment of the present invention, in the order of its steps.

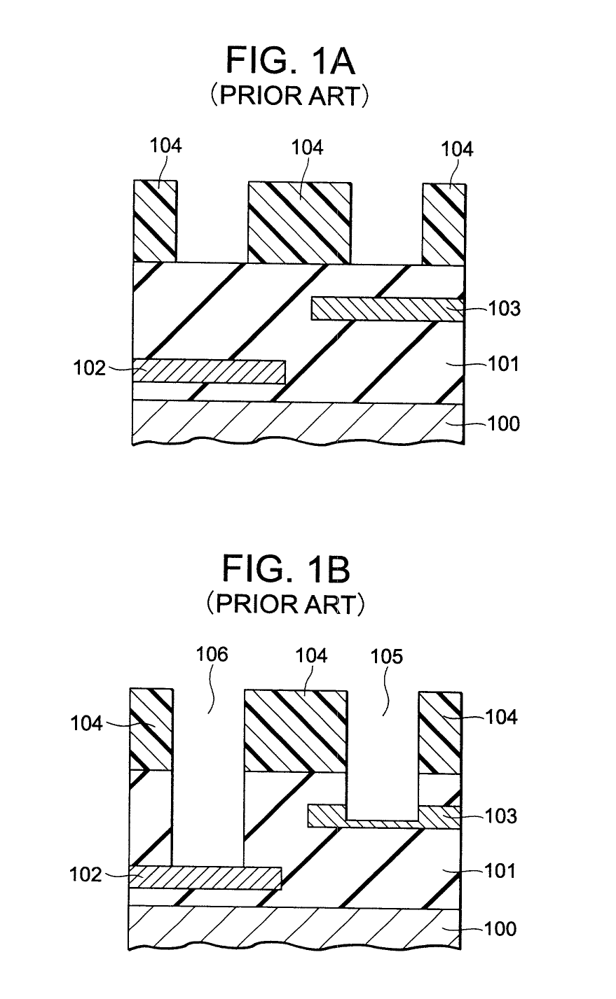

### DETAILED DESCRIPTION OF THE PREFERRED EMBODIMENTS

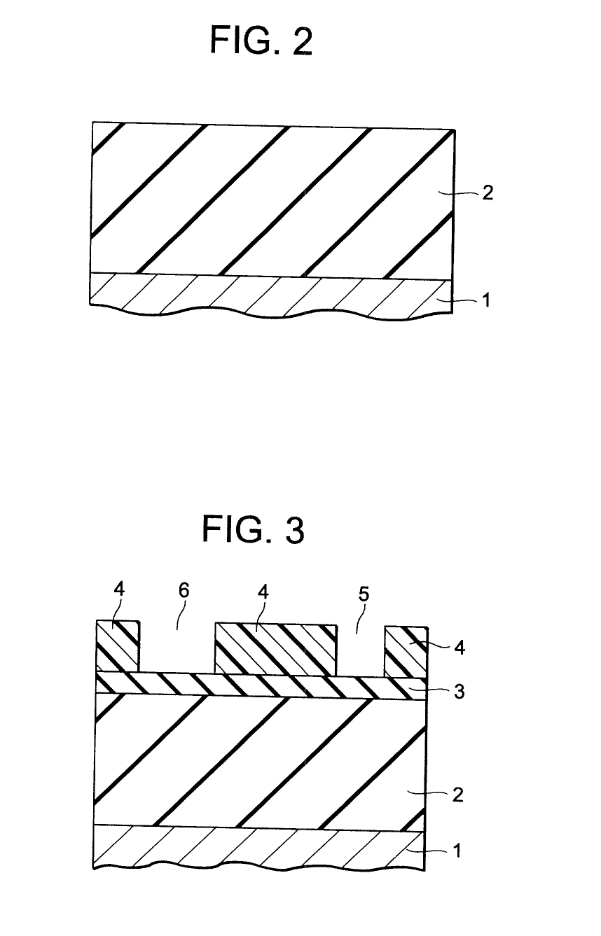

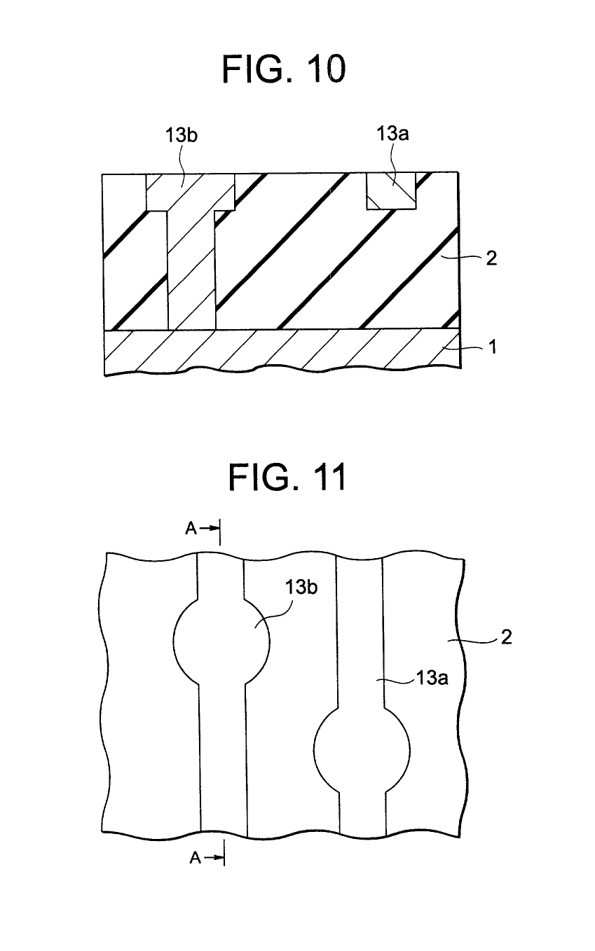

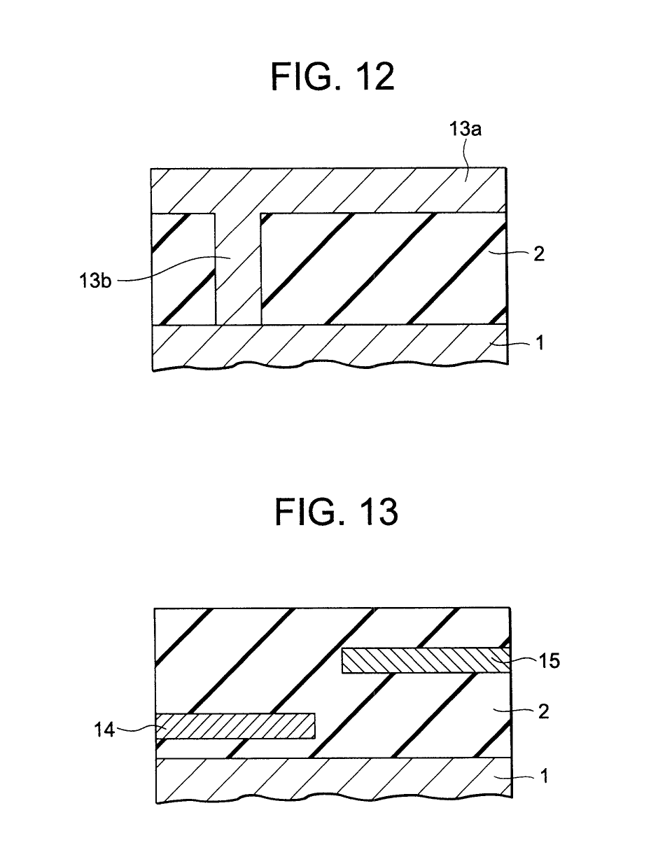

Hereinafter, preferred embodiments of the present invention will be described in detail with reference to the accompanying drawings. FIGS. 2 to 10 are sectional views which show the method for forming contacts or wiring in a semiconductor device according to a first embodiment of the present invention, in the order of its steps. FIG. 11 is a top view of FIG. 10, and FIG. 12 is a sectional view taken along the A-A line in FIG. 11.

Now, description will be given of the method for forming contacts or wiring in a semiconductor device according to the first embodiment of the present invention. As shown in FIG. 2, initially, an interlayer insulating film 2 which, for example, consists of SiO₂ and has a thickness of 1 μm is formed on a semiconductor substrate 1 consisting of e.g. a silicon substrate.

Then, as shown in FIG. 3, a first insulating film 3 which, for example, has a thickness of 150 nm and consists of SiN is deposited on the interlayer insulating film 2.

Next, a resist is applied onto the first insulating film 3 to form a resist film 4. The resist film 4 is then patterned by photolithography so as to have openings in an area 5 to form a wiring groove and an area 6 to form a contact hole. The area 5 is an area to form a wiring groove 7 in the subsequent process, having a width of e.g. 0.3 μm. The area 6 is an area to form a contact hole 11 in the subsequent process, having a width of e.g. 0.6 μm. In other words, the opening in the area 5 to form a wiring groove has a width smaller than the diameter of the opening in the area 6 to form a contact hole.

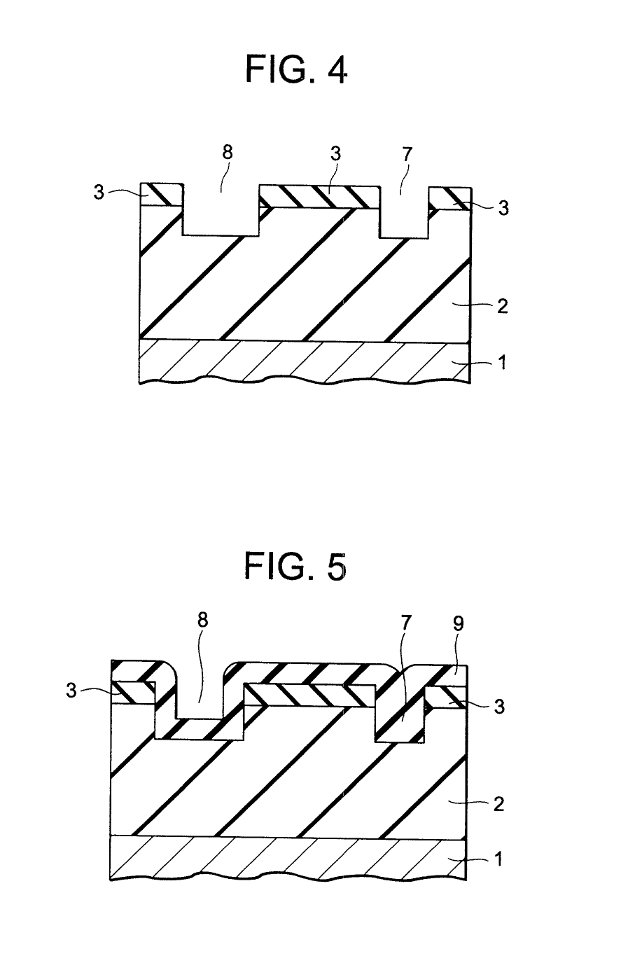

Subsequently, as shown in FIG. 4, the first insulating film 3 and the interlayer insulating film 2 are subjected to anisotropic dry etching with the resist film 4 as a mask, to the extent that the hole being formed in the interlayer insulating film 2 reach a depth, or etching amount, of 0.3 μm for example. This forms a hole 8 and a wiring groove 7 in the interlayer insulating film 2. Consequently, the wiring groove 7 is 0.3 μm in depth.

This is followed, as shown in FIG. 5, by deposition of a second insulating film 9 that has a thickness on the order of 180 nm and consists of SiN, for example. Here, the hole 8 must have the second insulating film 9 formed into a sidewall shape along its side surface whereas the wiring groove forming area 7 is filled with the second insulating film 9.

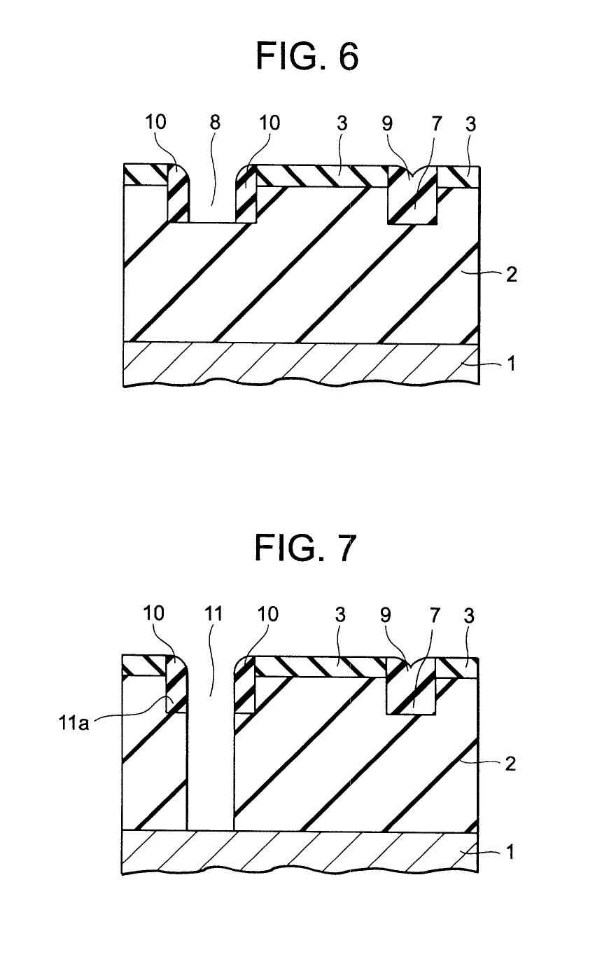

Then, as shown in FIG. 6, the second insulating film 9 is etched back by anisotropic dry etching to the extent that the interlayer insulating film 2 beneath the hole 8 is exposed totally. This results in a sidewall 10 in the hole 8.

Next, as shown in FIG. 7, the interlayer insulating film 2 beneath the hole 8 is etched by anisotropic dry etching with the sidewall 10 as a mask, forming a contact hole 11 which reaches to the semiconductor substrate 1.

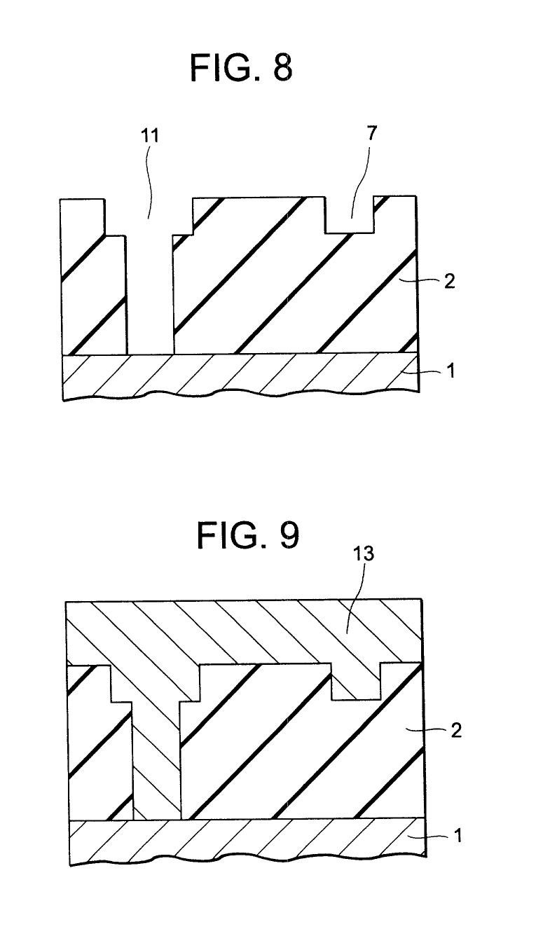

Thereafter, as shown in FIG. 8, the first insulating film 3, second insulating film 9, and sidewall 10 are etched back to remove the first insulating film 3, second insulating film 9, and sidewall 10 completely from the interlayer insulating film 2, wiring groove 7, and contact hole 11. This completes the contact hole 11 reaching to the semiconductor substrate 11, and the wiring groove 7.

In this etching, the interlayer insulating film 2 needs to be prevented from being etched. Thus, in the case where the interlayer insulating film 2 is made of e.g. SiO₂ and the first and second insulating films 3 and 9 are made of e.g. SiN, techniques such as wet etchback using thermal phosphoric acid are preferred.

As shown in FIG. 9, a wiring metal layer 13 consisting of the laminate structure of Cu, TiN, and Ti, having a thickness on the order of 500 nm is then deposited thereon by a chemical vapor deposition (CVD) method, for example.

Subsequently, as shown in FIG. 10, the wiring metal layer 13 is polished by e.g. CMP to expose the surface of the interlayer insulating film 2, thereby planarizing the surfaces of the interlayer insulating film 2 and the wiring metal layer 13. Consequently, as shown in FIGS. 11 and 12, the wiring metal layer 13 is left embedded in the wiring groove 7 and the contact hole 11, forming wiring 13a and a contact 13b, respectively. In this manner, both the wiring and the contact can be formed even by a single photolithographic process.

In the present embodiment, the area 6 to form a contact hole is formed to have a diameter greater than the width of the area 5 to form a wiring groove. As a result, the second insulating film 9, when deposited, forms a sidewall in the hole 8 while it fills the wiring groove 7. Accordingly, the interlayer insulating film 2 is not subjected to the etching at the wiring groove 7 in the contact hole forming process of FIG. 7. The etching has an effect only on the hole 8, so that the contact hole 11 reaching to the semiconductor substrate 1 is formed in the interlayer insulating film 2. This allows separate controls as to the depths of the wiring groove 7 and the contact hole 11. For the reason stated above, the wiring 13a and the contact 13b can be formed by a single photolithographic process.

In the present embodiment, it makes no difference whether the second insulating film 9 is identical to or different from the first insulating film 3 in type of material. The first insulating film 3 and second insulating film 9, however, must be of material that has selectivity to the interlayer insulating film 2 in the following dry etching process. Thus, the second insulating film 9 is preferably made of SiN, SiON, or the like.

Moreover, while in the present embodiment the wiring metal layer 13 consists of Cu, TiN, and Ti in laminate structure, the present invention is not particularly limited thereto and may adopt the laminate structure of W or Al with TiN and Ti, or the like. The deposition method may be high-temperature sputtering, electro deposition, or the like.

Furthermore, while in the present embodiment the wiring metal layer 13 is subjected to the CMP planarization, the present invention is not particularly limited thereto and may adopt etchback using dry etching or the like for planarization.

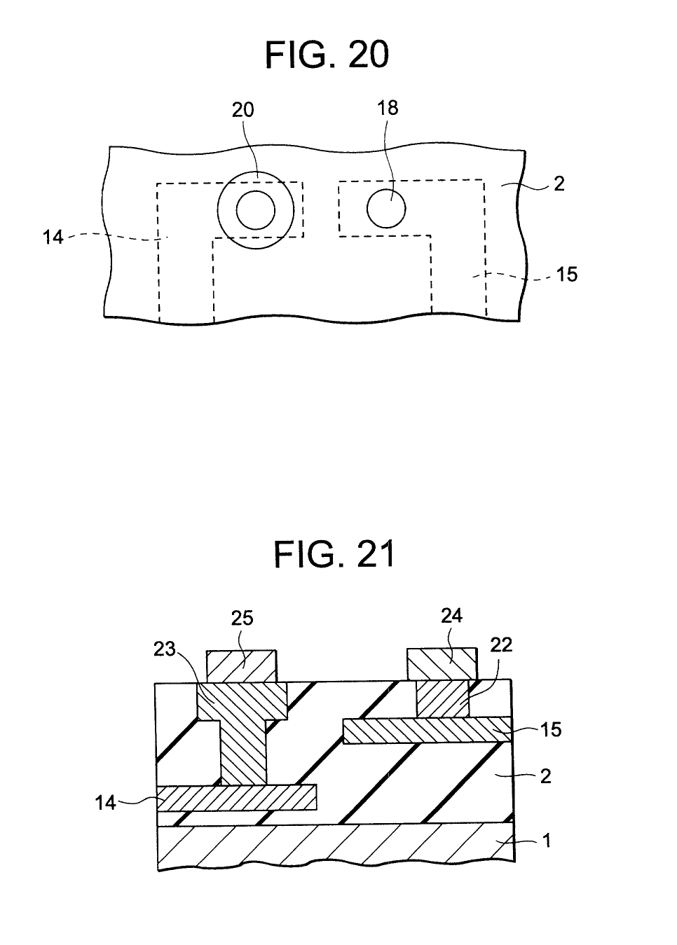

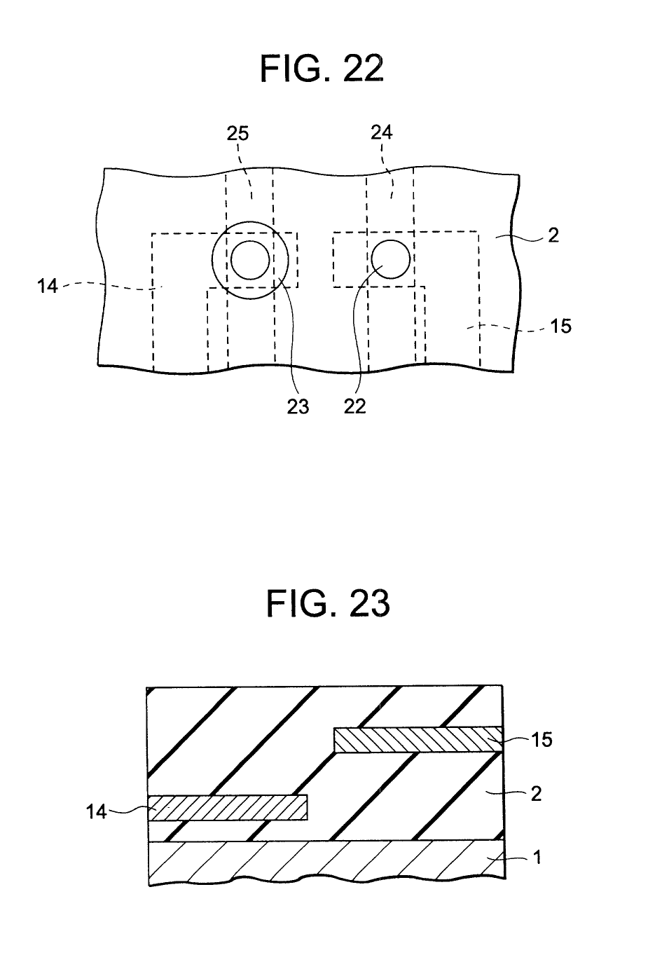

Now, a second embodiment of the present invention will be described with reference to FIGS. 13 through 22. Here, like parts of the first embodiment shown in FIGS. 2 through 12 will be designated by like reference numerals, and detailed description thereof will be omitted. FIGS. 13-19 and FIG. 21 are sectional views showing in the order of its processes the method for forming contacts in a semiconductor device according to the second embodiment of the present invention. FIG. 20 is a top view of FIG. 19, and FIG. 22 is a top view of FIG. 21.

The present embodiment is the same fabrication processes as those of the first embodiment except in that the wiring groove 7 is replaced with a shallow contact forming area 18 and the contact hole 11 replaced with a deep contact forming area 20.

In the present embodiment, as shown in FIG. 13, an interlayer insulating film 2 that has a thickness of 1 μm and consisting of SiO₂, for example, is initially formed on a semiconductor substrate 1 consisting of a silicon substrate. Here, a 150-nm-thickness first wiring layer 14 containing W and a 150-nm-thickness second wiring layer 15 containing W, for example, are embedded in the interlayer insulating film 2 so as to differ from each other in height within the interlayer insulating film 2.

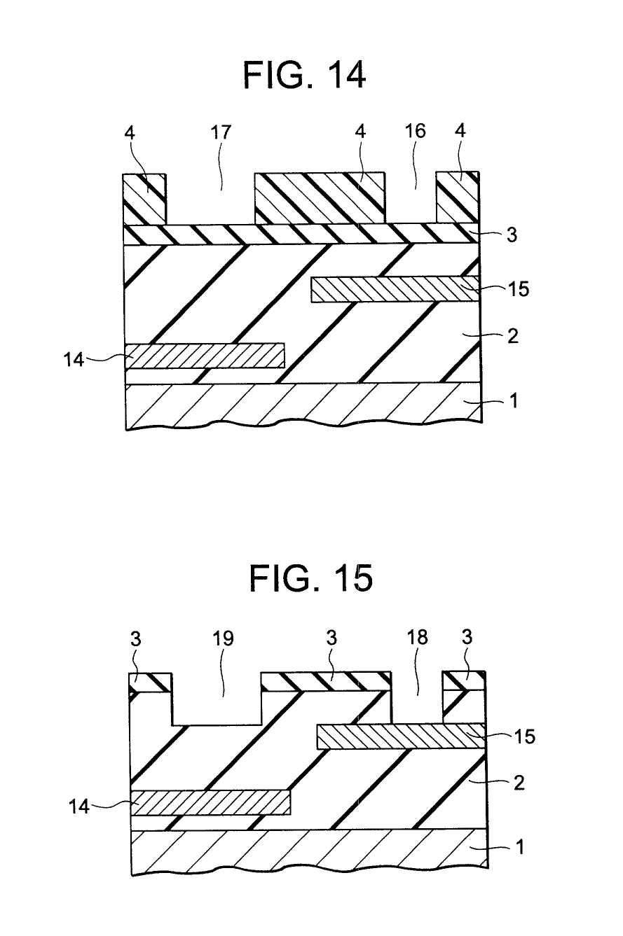

Then, as shown in FIG. 14, a 150-nm-thickness first insulating film 3 consisting of SiN, for example, is deposited on the interlayer insulating film 2.

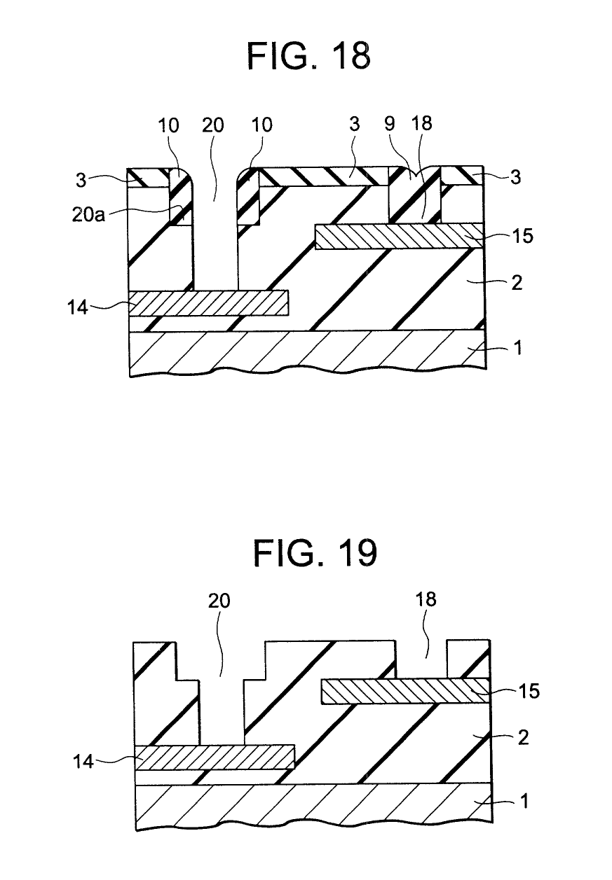

Next, a resist is applied onto the first insulating film 3 to form a resist film 4. The resist film 4 is then patterned by photolithography so as to have openings in a shallow area to form a contact hole 16 and a deep area to form a contact hole 17. The shallow area to form a contact hole 16 is an area to form a shallow contact hole 18 (see FIG. 15) in the subsequent process. The deep area to form a contact hole 17 is an area to form a deep contact hole 20 (see FIG. 18) in a later process. The shallow area to form a contact hole 16 has a width of e.g. 0.3 μm, and the deep area to form a contact hole 17 has a width of e.g. 0.6 μm. In other words, the shallow area to form a contact hole 16 is smaller in diameter than the deep area to form a contact hole 17.

Subsequently, as shown in FIG. 15, the first insulating film 3 and interlayer insulating film 2 are subjected to anisotropic dry etching with the resist film 4 as a mask. This anisotropic dry etching is carried on until a hole being formed in the interlayer insulating film 2 reaches to the second wiring layer 15. For example, the etch depth to the interlayer insulating film 2 is 0.3 μm. This forms a shallow contact hole 18 in the shallow area to form a contact hole 16. Meanwhile, in the deep area to form a contact hole 17 is formed a hole 19 which has a depth nearly equal to that of the contact hole 18.

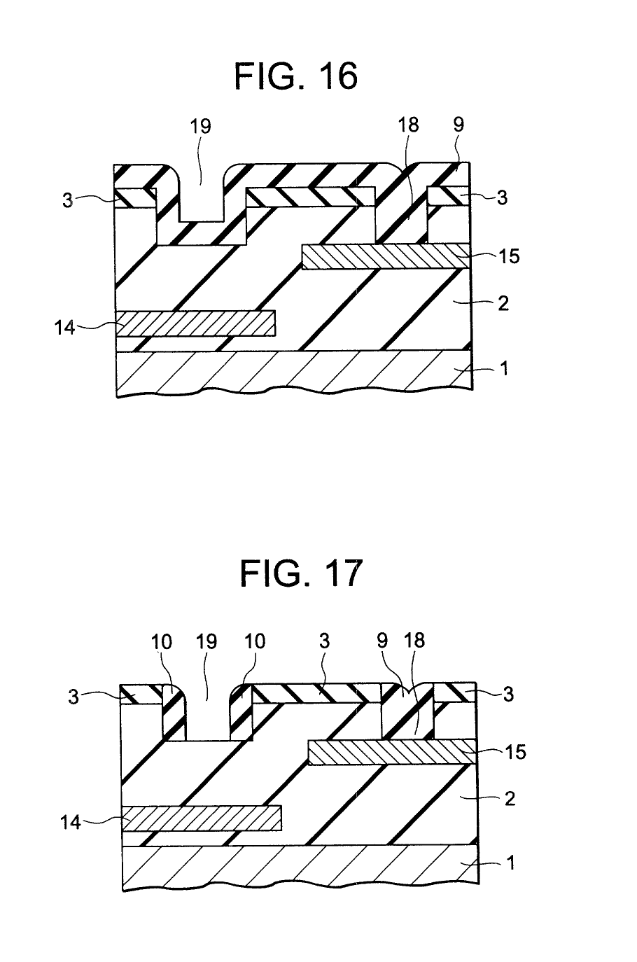

This is followed, as shown in FIG. 16, by deposition of a 180-nm-thickness second insulating film 9 consisting of SiN, for example. Here, the hole 19 must have the second insulating film 2 formed into a sidewall shape along its side surface, whereas the shallow contact hole 18 is filled with the second insulating film 9.

Then, as shown in FIG. 17, the second insulating film 9 is etched back by anisotropic dry etching so that the interlayer insulating film 2 beneath the hole 19 is totally exposed. This results in forming of a sidewall 10 in the hole 19.

Next, as shown in FIG. 18, the interlayer insulating film 2 beneath the hole 19 is etched by anisotropic dry etching with the first insulating film 3, second insulating film 9, and sidewall 10 as masks. This forms a deep contact hole 20 which reaches to the first wiring layer 14.

Thereafter, as shown in FIGS. 19 and 20, the first insulating film 3, second insulating film 9, and sidewall 10 are etched back to remove the first insulating film 3, second insulating film 9, and sidewall 10 perfectly. This completes the deep contact hole 20 reaching to the first wiring layer 14, and the shallow contact hole 18 reaching to the second wiring layer 15.

In this etching, the interlayer insulating film 2 needs to be prevented from being etched. For that purpose, a gas having high etch selectivity is used for the etching gas. For example, in the case where the interlayer insulating film 2 is made of an oxide film such as SiO₂ or BPSG and the first and second insulating films 3 and 9 are made of a nitride film of SiN, etching gases such as Cl₂ are preferred.

Subsequently, both the deep contact hole 20 and the shallow contact hole 18 are filled with a metal containing W or the like, for example, to form metal plugs. This is followed by deposition of a third wiring layer that contains Al or the like, for example. The third wiring layer is then patterned into a wiring shape. This, as shown in FIGS. 21 and 22, forms electrodes 24 and 25 consisting of the third wiring layer, and results in the deep contact 23 and shallow contact 22 establishing connection between the first and second wiring layers 14, 22 and the electrodes 24, 25, respectively. In this manner, both the shallow contact 22 and the deep contact 23 can be formed even by a single photolithographic process.

In the present embodiment, the deep area to form a contact hole 17 is formed greater in diameter than the shallow area to form a contact hole 16. As a result, the second insulating film 9, when deposited, forms a sidewall shape in the deep hole 19 while it fills the shallow contact hole 18. Accordingly, the shallow contact hole 18 is prevented from being etching further, and etching proceeds only in the hole 19 for forming a deep contact. This provides separate controls as to the depths of the shallow contact hole 18 and the deep contact hole 20. For the reason stated above, it is possible to form both the shallow contact hole 18 and the deep contact hole 20 by a single photolithographic process.

Now, a third embodiment of the present invention will be described with reference to FIGS. 23 through 28. Here, like parts of the second embodiment shown in FIGS. 13 through 22 will be designated by like reference numerals, and detailed description thereof will be omitted. FIGS. 23 through 28 are sectional views showing in the order of its processes the method for forming contacts in a semiconductor device according to the third embodiment of the present invention.

The present embodiment is the same fabrication method as that of the second embodiment except in that the processes for forming contact holes are small in number.

In the present embodiment, as shown in FIG. 23, a 1 μm thickness interlayer insulating film 2 consisting of SiO₂, for example, is initially formed on a semiconductor substrate 1 consisting of a silicon substrate. Here, a 150-nm-thickness first wiring layer 14 comprising W and a 150-nm-thickness second wiring layer 15 comprising W are formed within the interlayer insulating film 2, for example.

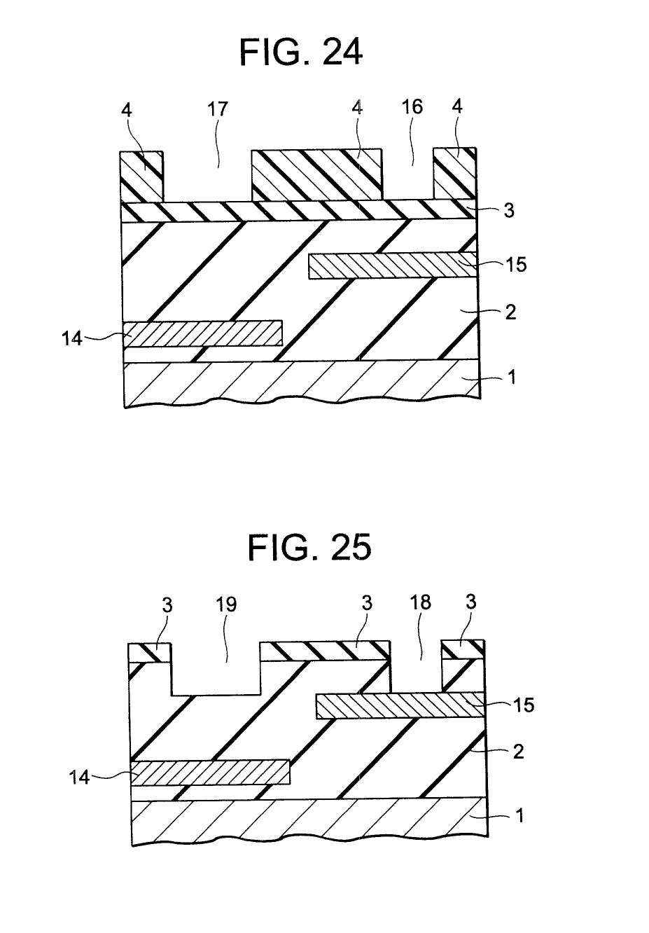

Then, as shown in FIG. 24, a 150-nm-thickness first insulating film 3 of SiN, for example, is deposited on the interlayer insulating film 2. This first insulating film 3 is preferably made of material that has etch selectivity to the interlayer insulating film 2 in the dry etching which is performed in a later process.

Next, a resist is applied onto the first insulating film 3 to form a resist film 4. The resist film 4 is then patterned by photolithography so that an area 16 to form a shallow contact hole 16 in a later process has a width of e.g. 0.24 μm and an area to form a deep contact hole 26 in a later process has a width of e.g. 0.6 μm. In short, the area 16 is smaller in diameter than the area 17.

Subsequently, as shown in FIG. 25, the first insulating film 3 and interlayer insulating film 2 are subjected to anisotropic dry etching with the resist film 4 as a mask. This forms in the interlayer insulating film 2 a shallow contact hole 18 which reaches to the second wiring layer 15. Here, the etching amount to the interlayer insulating film 2 is, for example, 0.3 μm. Meanwhile, in the area 17 to form a deep contact hole is formed a hole 19.

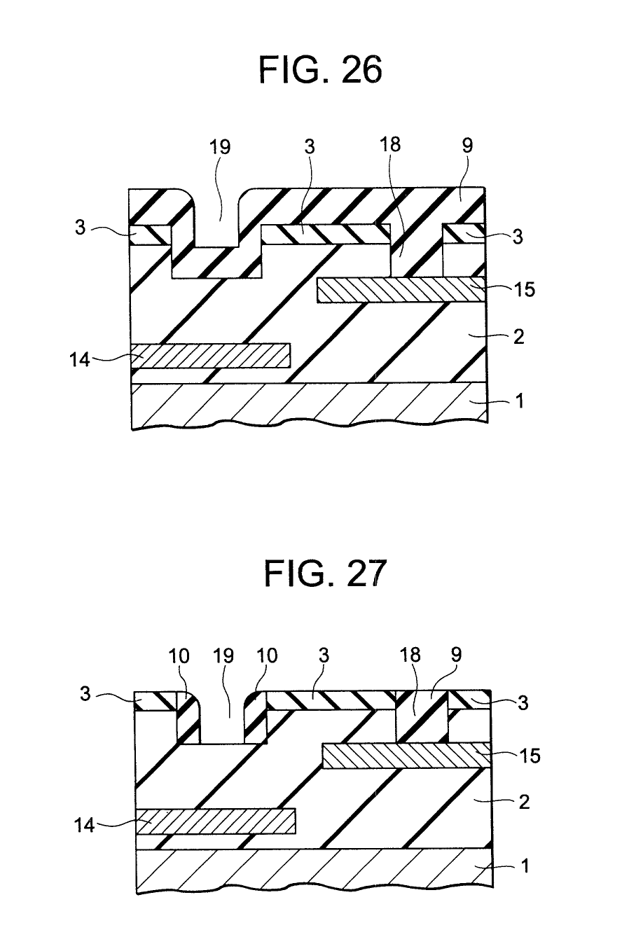

This is followed, as shown in FIG. 26, by deposition of a second insulating film 9 that consists of SiN and has a thickness on the order of 240 nm, for example. Here, the hole 19 must have the second insulating film 9 formed into a sidewall shape along its side surface, while the shallow contact hole 18 is filled with the second insulating film 9.

Then, as shown in FIG. 27, the second insulating film 9 is etched back by anisotropic dry etching to the extent that the interlayer insulating film 2 beneath the hole 19 is totally exposed, leaving a sidewall 10 in the hole 19.

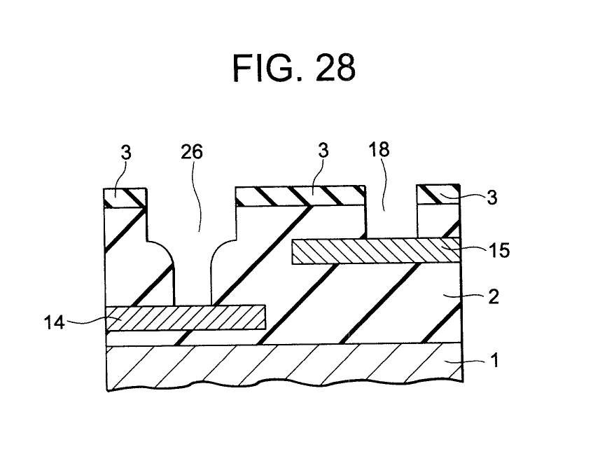

As shown in FIG. 28, the interlayer insulating film 9, sidewall 10, and interlayer insulating film 2 are subsequently etched back so that the hole 19 reaches to the first wiring layer 14, forming a deep contact hole 26 reaching to the first wiring layer 14. This etchback to the interlayer insulating film 9, sidewall 10, and interlayer insulating film 2 completes the deep contact hole 26 and the shallow contact hole 18.

Thereafter, though omitted of illustration, both the deep contact hole 26 and the shallow contact hole 18 are filled with metal consisting of W or the like, for example, to form metal plugs as in the second embodiment. Then, a third wiring layer (omitted of illustration) that contains Al or the like, for example, is deposited thereon, followed by patterning. This forms electrodes 24 and 25 consisting of the third wiring layer, and results in the deep contact 23 and shallow contact 22 establishing connection between the first and second wiring layers 14, 15 and the electrodes 24, 25, respectively (see FIGS. 21 and 22).

Note that the previous, second embodiment requires the three etchbacks after the deposition of the second insulating film 9; namely, the etchback to the second insulating film 9, the etchback to the interlayer insulating film 2, and the etchback to the first insulating film 3, second insulating film 9, and sidewall 10. In contrast, the present embodiment requires only two etchbacks after the deposition of the second insulating film 9; that is, the etchback to the second insulating film 9, and the etchback to the sidewall 10 and interlayer insulating film 2. This has an advantage in that the number of the processes is reducible as compared to that of the second embodiment. The simultaneous formation of the deep and shallow contact holes 26 and 18, however, has a drawback in slightly inferior controllability to the shallow contact hole 18 as compared with the second embodiment.

For the purpose of etchback, the second insulating film 9 in the present embodiment needs to have an etch rate equivalent to that of the interlayer insulating film 2, as well as selectivity to the material of the first insulating film 3. SiO₂ can be appropriately used as the material of the second insulating film 9.

While in the second and third embodiments described above the first and second wiring layers 14 and 15 adopt W as their material, the present invention is not limited thereto and may use such materials as poly-crystalline silicon (hereinafter, referred to as poly-Si), WSi, Al, Cu, TiN, or laminate structures thereof.

Moreover, while in the second and third embodiments described above the first and second wiring layers 14 and 15 adopt W as their material, replacement of W with poly-Si allows such treatments as wet etchback using thermal phosphoric acid, as in the first embodiment, in the etching process for forming both the deep contact hole 20 (26) reaching to the first wiring layer 14 and the shallow contact hole 18 if the interlayer insulating film 2 consists of e.g. SiO₂ and the first and second insulating films 3 and 9 consist of e.g. SiN.

Any of the embodiments described above uses SiO₂ for the interlayer insulating film 2; however, the present invention is not limited thereto and may use BPSG, PSG, laminate structures thereof, or the like.

The deposition of the second insulating film 9 is preferably performed by an LP-CVD method which is superior in step coverage.

Moreover, the etchback to the interlayer insulating film 2 requires use of a gas having higher selectivity so as to prevent the second insulating film 9 and first insulating film 3 from being etched. The interlayer insulating film 2 consisting of an oxide film such as SiO₂ or BPSG and the first and second insulating films 3 and 9 consisting of a nitride film of SiN or the like prefer etching gases such as C₄F₈. The first insulating film 3 is preferably made of material that has selectivity to the interlayer insulating film 2 in the following dry etching process.

Even in the above-described embodiments, the materials of the components, the film-forming methods, and the various numerical values are not limited to those stated above. Appropriate changes may be made thereto as far as the present invention is applicable.

In the present invention, as has described in detail, the area to form a contact hole is formed to have a diameter greater than the width of the area to form a wiring groove so that, when the second insulating film is deposited thereon, the area to form a contact hole has the second insulating film formed into a sidewall shape along its side surface while the area to form a wiring groove is filled with the second insulating film. This provides separate controls as to the depths of the wiring groove and the contact hole. Accordingly, both wiring and contacts can be formed by a single photolithographic process rather than by a plurality of photolithographic processes.

Similarly, the area to form a deep contact hole is formed greater in diameter than the area to form a shallow contact hole so that, when the second insulating film is deposited thereon, the area to form a deep contact hole has a hole where the second insulating film formed into a sidewall shape along its side surface while the area to form a shallow contact hole is filled with the second insulating film, allowing separate controls as to the depths of the shallow contact hole and the deep contact hole. Accordingly, shallow contacts and deep contacts can be formed by a single photolithographic process, reducing damage to wiring layers as well as preventing the wiring layers from perforation and the like.

What is claimed is:

1. A method for forming contact or wiring in a semiconductor device, comprising the steps of:
forming an interlayer insulating film on a semiconductor substrate;
forming a first insulating film on said interlayer insulating film; and
applying a resist on said first insulating film and then patterning the same to form a first opening and a second opening at an area to form a contact hole and an area to form a wiring groove, respectively, a diameter of the first opening at the area to form the contact being greater than the width of the second opening at the area to form the wiring groove.

2. The method for forming contact or wiring in a semiconductor device according to claim 1, further comprising the steps of, after patterning the resist:
forming a hole and a wiring groove at the area of the first opening and the area of second opening, respectively, in the first insulating film and the interlayer insulating film;
forming a second insulating film over said hole and said wiring groove and forming a sidewall in said hole at the area to form a contact hole as well as fill said wiring groove therewith;
forming a contact hole at said hole in the interlayer insulating film by etching back said interlayer insulating film with said sidewall and said second insulating film as a mask; and
removing said sidewall and said second insulating film.

3. A method for forming contacts or wiring in a semiconductor device, comprising the steps of:
forming an interlayer insulating film on a semiconductor substrate;
forming a first insulating film on said interlayer insulating film; and
applying a resist on said first insulating film and then patterning the same to form a first opening and a second opening at an area to form a deep contact hole and an area to form a shallow contact hole, respectively, a diameter of the first opening at the area to form the deep contact hole being greater than a diameter of the second opening at the area to form a shallow contact hole.

4. The method for forming contacts or wiring in a semiconductor device according to claim 3, further comprising the steps of, after patterning the resist:
forming a hole and a shallow contact hole at the area of the first opening and the area of the second opening, respectively, in the first insulating film and the interlayer insulating film;
forming a second insulating film over said hole and said shallow contact hole and forming a sidewall in said hole at the area to form a deep contact hole as well as fill said shallow contact hole therewith;
forming a deep contact hole at said hole in the interlayer insulating film by etching back said interlayer insulating film with said sidewall and said second insulating film as a mask; and
removing said sidewall and said second insulating film.

5. The method for forming contacts or wiring in a semiconductor device according to claim 3, further comprising the steps of, after patterning the resist:
forming a hole and a shallow contact hole at the are of the first opening and the area of the second opening, respectively, in the first insulating film and the interlayer insulating film;
forming a second insulating film over said hole and said shallow contact hole and forming a sidewall in said hole at the area to form a deep contact hole as well as fill said shallow contact hole therewith; and
etching back said interlayer insulating film with said sidewall and said second insulating film as a mask and then etching back said sidewall and said second insulating film to form a deep contact hole and remove said second film in said shallow contact hole simultaneously.

6. The method for forming contacts or wiring in a semiconductor device according to claim 1, wherein
said interlayer insulating film is made of one material selected from the group consisting of SiO₂, BPSG, and PSG, or any laminate structure of the same.

7. The method for forming contacts or wiring in a semiconductor device according to claim 2, wherein said interlayer insulating film is made of one material selected from the group consisting of SiO₂, BPSG, and PSG, or any laminate structure of the same.

8. The method for forming contacts or wiring in a semiconductor device according to claim 3, wherein
said interlayer insulating film is made of one material selected from the group consisting of SiO₂, BPSG, and PSG, or any laminate structure of the same.

9. The method for forming contacts or wiring in a semiconductor device according to claim 4, wherein
said interlayer insulating film is made of one material selected from the group consisting of SiO₂, BPSG, and PSG, or any laminate structure of the same.

10. The method for forming contacts or wiring in a semiconductor device according to claim 5, wherein
said interlayer insulating film is made of one material selected from the group consisting of SiO₂, BPSG, and PSG, or any laminate structure of the same.
